(19) United States
(12) Patent Application Publication
(10) Pub. No.: US 2006/0084220 A1
(43) Pub. Date: Apr. 20, 2006

(54) Differentially nitrided gate dielectrics in CMOS fabrication process

(75) Inventors: Sangwoo Lim, Austin, TX (US); Paul A. Grudowski, Austin, TX (US); Dejan Jovanovic, Corenc (FR); Choh-Fei Yeap, San Diego, CA (US)

Correspondence Address: FREESCALE SEMICONDUCTOR, INC., MDTX32/PLO2, 770 W PARMER LANE, AUSTIN, TX, 78729, US

(73) Assignee: Freescale Semiconductor, Inc.

(21) Appl. No.: 10/965,963

(22) Filed: Oct. 15, 2004

(51) Int. Cl. H01L 21/8234; H01L 21/8238; H01L 21/336

(52) U.S. Cl. 438/216; 438/287; 438/197

(57) ABSTRACT

A semiconductor fabrication process includes forming a first plasma nitrided oxide (PNO) gate dielectric overlying a first region of a semiconductor substrate. A second PNO gate dielectric is formed overlying a second region of the substrate. The nitrogen concentration of the second PNO differs from the nitrogen concentration of the first PNO. A PMOS transistor is formed overlying the first substrate region and an NMOS transistor overlying the second substrate region. Prior to forming the first PNO gate dielectric, a mobility enhancing channel region may be formed overlying the first substrate region. Forming the mobility enhancing channel region may include forming a compressively stressed silicon germanium film overlying the first substrate region.

### FIELD OF THE INVENTION

The present invention is in the field of semiconductor fabrication processes and more specifically, CMOS fabrication processes.

### RELATED ART

In CMOS fabrication processes, much effort has been devoted recently to improving the performance characteristics of the PMOS devices. Such efforts include processes that attempt to improve the PMOS I_{ON}-I_{OFF} characteristics. The I_{ON}-I_{OFF} characteristics identify the saturated drain current (I_{ON}) as a function of the subthreshold current (I_{OFF}). The I_{ON}-I_{OFF} characteristics are an important parameter for PMOS devices and the goal is to achieve the highest possible value of I_{ON} for a given value of I_{OFF}.

Unfortunately, processes that tend to improve PMOS I_{ON}-I_{OFF} characteristics also tend to have detrimental affects on other performance parameters including, as examples, the NMOS carrier mobility and the PMOS V_{T}. It would be desirable, therefore, to implement a fabrication process in which PMOS and NMOS performance parameters are uniformly improved without substantially increasing the complexity of the fabrication process.

### BRIEF DESCRIPTION OF THE DRAWINGS

The present invention is illustrated by way of example and not limited by the accompanying figures, in which like references indicate similar elements, and in which:

FIG. 1 is a partial cross-sectional view of a wafer at a selected stage in a semiconductor fabrication process illustrating the formation of a silicon germanium film overlying a PMOS region of the wafer substrate;

FIG. 2 depicts processing subsequent to FIG. 1 in which a heavily nitrided gate dielectric is formed overlying the wafer;

FIG. 3 depicts processing subsequent to FIG. 2 in which the heavily nitrided gate dielectric is selectively removed overlying NMOS regions of the wafer;

FIG. 4 depicts processing subsequent to FIG. 3 in which a lightly nitrided gate dielectric is formed overlying NMOS regions of the wafer;

FIG. 5 depicts processing subsequent to FIG. 4 in which PMOS and NMOS transistors are formed;

FIG. 6 depicts processing subsequent to FIG. 1 according to a second embodiment in which a lightly nitrided gated dielectric is formed overlying the wafer;

FIG. 7 depicts processing subsequent to FIG. 6 in winch portions of the lightly nitrided gate dielectric are removed overlying NMOS regions of the wafer; and

FIG. 8 depicts processing subsequent to FIG. 7 in which a heavily nitrided gate dielectric is formed overlying NMOS regions of the wafer;

FIG. 9 depicts processing subsequent to FIG. 1 according to a third embodiment in which a relatively thick, lightly doped gate dielectric is formed;

FIG. 10 depicts processing subsequent to FIG. 9 in which the first gate dielectric is removed overlying PMOS regions of the wafer; and

FIG. 11 depicts processing subsequent to FIG. 10 in which a relatively thin gate dielectric is formed overlying the PMOS regions.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

Generally speaking, the present invention is concerned with achieving desirable PMOS I_{ON}-I_{OFF} characteristics while not simultaneously negatively impacting the PMOS threshold voltage (V_{T}) or any parameter associated with the NMOS devices. The PMOS I_{ON}-I_{OFF} characteristics are improved by incorporating nitrogen into and scaling the thickness of the gate dielectric. The resulting I_{ON}-I_{OFF} improvement is accompanied, unfortunately, but an undesirable increase in PMOS V_{T}. To offset the V_{T} shift while achieving additional PMOS transistor performance improvement, the PMOS devices are formed overlying a channel region comprised of a mobility-enhancing material such as compressively stressed silicon germanium (which is mobility-enhancing for holes). A silicon germanium channel region lower the PMOS V_{T} by approximately 200 to 250 mV due to band offset. The V_{T} shift caused by the use of silicon germanium offsets the V_{T} shift caused by using a plasma nitrided oxide (PNO) with a high nitrogen concentration for the PMOS gate dielectric. In addition to improving I_{ON}-I_{OFF} and offsetting the PMOS V_{T}, the nitrided PNO provides an effective barrier to leakage and mobile impurities. NMOS device parameters are preserved by implementing the high concentration PNO and SiGe selectively, in the PMOS regions only. By combining the I_{ON}-I_{OFF} benefits of using a scaled PNO PMOS gate dielectric with the PMOS channel mobility improvement attributable to an SiGe channel region, PMOS transistor performance is doubly improved. Moreover, because the V_{T} shifts caused by the PNO and the SiGe offset one another, the performance improvement is achieved without significantly altering the PMOS V_{T} thereby greatly facilitating the integration of the PMOS improvements into existing fabrication processes.

Referring now to FIG. 1, a wafer 100 is depicted in partial cross-section at a first stage in a semiconductor fabrication process according to one embodiment of the present invention. The starting material for wafer 100, depending upon the implementation, may include a conventional bulk silicon substrate. Alternatively, wafer 100 may be a silicon-on-insulator (SOI) wafer. In the SOI wafer embodiment, wafer 100 includes a semiconductor top layer, which would be represented by regions 104 and 106, overlying a buried oxide (BOX) layer (not shown) overlying a silicon bulk.

FIG. 1 depicts an isolation structure 110 formed between first region 106 and second region 104. Isolation structure 110 provides physical and electrical isolation between adjacent transistors. The depicted embodiment of isolation structure 110 is a shallow trench isolation (STI) structure. In other embodiments, isolation structure 110 may be a LOCOS structure that will be familiar to those in the field of semiconductor fabrication processes.

First region 106 is likely to be of a first conductivity type (n-type or p-type) while second region 104 is likely to be of a second conductivity type where the first and second types of majority carriers are different. In the implementation depicted in FIG. 1, first region 106 is a PMOS region while second region 104 is an NMOS regions. PMOS region 106 is a region upon which PMOS transistors will be formed while NMOS region 104 is a region upon which NMOS transistors will be formed. In this embodiment, PMOS region 106 has n-type conductivity while NMOS region 104 has p-type conductivity.

FIG. 1 depicts the formation of a semiconductor film 108 selectively overlying first region 106 of substrate 102. Semiconductor film 108 will serve as a mobility-enhancing channel region of a subsequently formed transistor. For PMOS transistors, a mobility-enhancing channel region is a region in which the mobility of p-type carriers (i.e., holes) is greater than the hole mobility in other portions of the substrate. For NMOS transistors, a mobility-enhancing channel region is a region in which the mobility of n-type carriers (i.e., electrons) is greater than the electron mobility in other portions of the substrate. In an embodiment where first region 106 is a PMOS region, semiconductor film 108 is preferably a compressively stressed semiconductor as formed overlying silicon. Silicon germanium (SiGe), for example, has a lattice constant that is greater than the lattice constant of the underlying silicon. For an implementation in which semiconductor film 108 is SiGe, the film will exhibit compressive stress as it formed on the underlying silicon.

In one embodiment, semiconductor film 108 is formed by selective epitaxial growth. In this embodiment, a hard mask (silicon nitride overlying a pad oxide, for example) is deposited over wafer 100 and patterned to expose the second region 106. An epitaxial process is then performed in a germanium-bearing ambient to form semiconductor film 108. In this embodiment, it will be appreciated that the epitaxial semiconductor film 108 will form as a single crystal film suitable for use a transistor channel region. Although an epitaxial embodiment of film 108 has advantageous crystalline properties, other implementations may employ a CVD or PVD silicon germanium film or a silicon germanium film formed by implanting germanium into a silicon substrate followed by an anneal.

The use of an epitaxial SiGe film 108 in an embodiment of the invention where first region 106 is a PMOS region of wafer 100 beneficially improves the performance of PMOS devices. It is known, for example, that hole mobility is greater in compressively stressed SiGe than in conventional silicon. In addition, PMOS transistors formed overlying a SiGe channel exhibit lower threshold voltages (˜200 to 250 mV in absolute value terms) than comparable transistors overlying conventional silicon channels because of band offset. The lower V_{T} characteristic of SiGe channels is offset, in one embodiment of the present invention, by incorporating nitrogen in the gate dielectric. The nitrogen tends to raise the PMOS V_{T}, but beneficially reduces impurity migration across the gate dielectric-gate electrode interface. Ideally, the V_{T} shift attributable to the SiGe channel is offset by the V_{T} shift attributable to the nitrogen. Combining SiGe transistor channels with nitrogen incorporation achieves improved carrier mobility and reduced impurity migration without a significant shift in V_{T}.

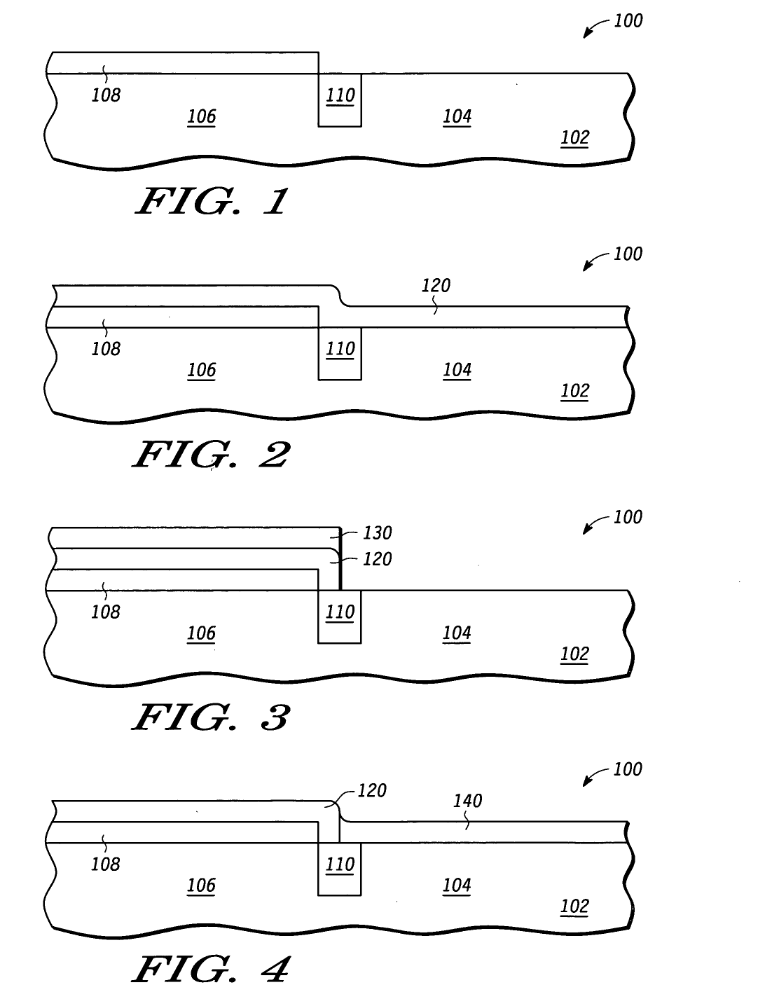

Referring now to FIG. 2, a first gate dielectric film 120 is blanket formed overlying wafer 100. The present invention may include the use of a gate dielectric for PMOS devices that differs from the gate dielectric used for NMOS devices. The PMOS gate dielectric and the NMOS gate dielectric may differ in composition, thickness, or both.

In one embodiment, first gate dielectric 120, which will serve as the PMOS gate dielectric, is a silicon-oxygen-nitrogen compound having a relatively high overall nitrogen concentration. Preferably, the nitrogen is distributed within the gate dielectric wherein the peak nitrogen concentration is located in proximity to the gate dielectric-gate electrode interface. For embodiments in which first gate dielectric 120 serves as the PMOS gate dielectric, first gate dielectric is preferably a PNO gate dielectric having a nitrogen concentration of greater than approximately 5% (by atomic weight). The PNO formation process includes a thermal oxidation that produces a conventional silicon-oxide film (SiO₂). The thermally formed film is then subjected to a nitrogen plasma and a subsequent anneal to form the PNO.

Nitrogen-containing gate dielectrics are highly desirable for transistors having effective lengths in the sub-250 nm range. Plasma nitrided oxides, in particular, are desirable to reduce leakage and gate-to-substrate boron penetration without exacerbating negative bias temperature instability (NBTI) associated with large concentrations of nitrogen at the oxide-substrate interface. In one embodiment, first gate dielectric 120 has an effective oxide thickness (EOT) in the range of approximately 1 to 2 nm. The heavily nitrided first gate dielectric is believed to produce an improvement in the I_{ON}-I_{OFF} characteristics of PMOS devices due, at least in part, to the lower EOT of the heavily nitrided film. Experimental results show an improvement (increase) of approximately 6% in I_{ON}-I_{OFF} for heavily nitrided PNO films in short-channel PMOS devices. A 6% improvement in I_{ON}-I_{OFF} is defined for purposes of this disclosure as an improvement of 6% in I_{ON}, for a given value of I_{OFF}. Referring now to FIG. 3, a photoresist mask 130 is patterned over first gate dielectric 120 to expose portions of gate dielectric 120 overlying the second region 104 of wafer 100. Thereafter, the exposed portions of first gate dielectric 120 are etched or otherwise removed to expose the second region 104.

Referring now to FIG. 4, a second gate dielectric film 140 is formed overlying second region 104 of substrate 102. According to one embodiment in which first region 106 is a PMOS region and second region 104 is an NMOS region, second gate dielectric 140 is a relatively-lightly nitrided silicon oxide compound. In this embodiment, second gate dielectric 140 may be implemented as a second PNO gate dielectric where the nitrogen concentration of second gate dielectric 140 differs from and is less than the nitrogen concentration of first gate dielectric 120.

The PNO formation parameters are alterable to control the amount of film deposited overlying first gate dielectric 120 during deposition of second dielectric 140. In one embodiment, for example, the formation of second gate dielectric 140 does not increase or only minimally increases the thickness of first gate dielectric 120. In other embodiments, the formation of second gate dielectric 140 may contribute to the thickness of first gate dielectric 120. In either embodiment, however, the formation of second gate dielectric 140 may increase or otherwise contribute to the concentration of nitrogen in first gate dielectric 120. Specifically, during the plasma nitridation of second gate dielectric 140, first gate dielectric 120 is exposed to the nitrogen plasma, which may increase the nitrogen concentration of first gate dielectric 120. If, for example, first gate dielectric 120 has an as-formed nitrogen concentration of approximately 5%, the formation of a second gate dielectric 140 having a nitrogen concentration of approximately 3% might result in first gate dielectric 120 having a nitrogen concentration of approximately 8%. In still other embodiments, first gate dielectric 140 may be masked (using photoresist or hard mask) during the deposition of second gate dielectric 140.

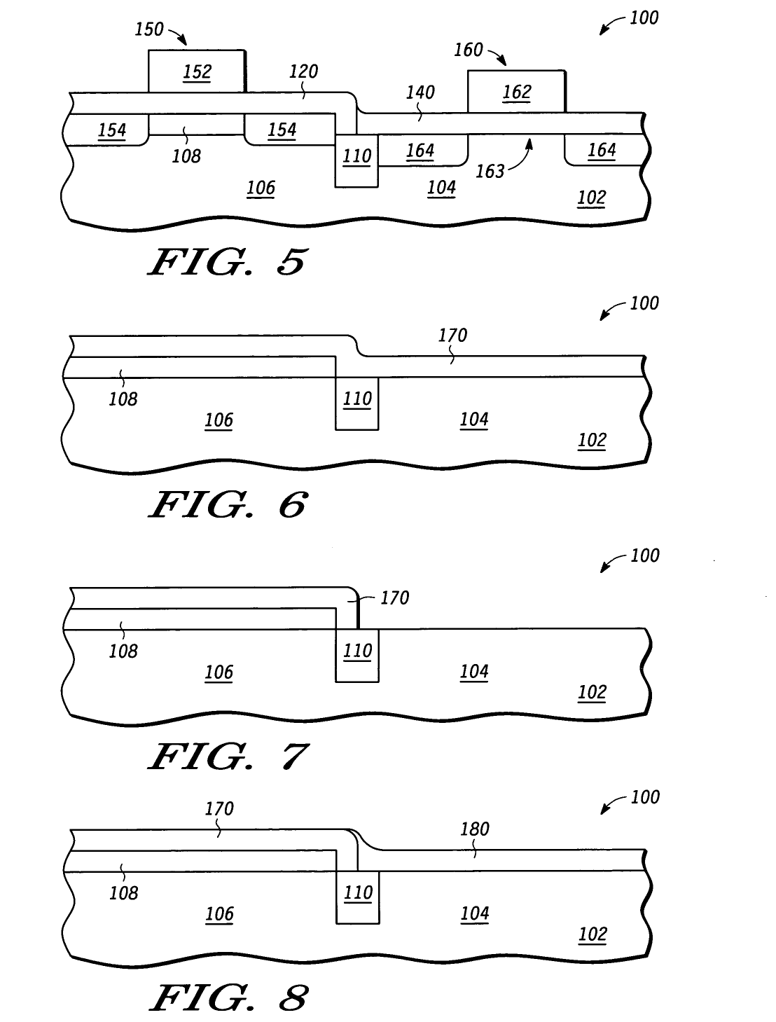

Referring now to FIG. 4, wafer 100 includes a first gate dielectric 120 having a first nitrogen concentration overlying semiconductor film 108. Semiconductor film 108 overlies a first region 104 of wafer substrate 102. A second gate dielectric 140 having a second nitrogen concentration overlies a second region 104 of the substrate 102. Semiconductor film 108 is a different semiconductor material than the semiconductor of substrate 102. Subsequent processing, the results of which are shown in FIG. 5, produce a first transistor in the first region 106 and a second transistor in the second region.

Referring now to FIG. 5, wafer 100 includes an integrated circuit having a first transistor 150 and a second transistor 160 formed over a monolithic substrate 102. In the depicted embodiment, first transistor 150 is preferably a PMOS transistor having a p-doped gate electrode 152 and p-doped source/drain regions 154. The source/drain regions 154 are displaced on either side of a PMOS channel region that underlies the gate electrode 152 and the gate dielectric 120. The PMOS channel region includes the portion of semiconductor film 108 positioned between the source/drain regions 154. As described above, semiconductor film 108 is preferably a compressively stressed SiGe film. Gate dielectric 120 is preferably a PNO film having a concentration of nitrogen in excess of approximately 5.0%.

Second transistor 160 preferably includes an n-doped gate electrode 162 overlying a second gate dielectric 140, which overlies an NMOS region 106 of substrate 102. N-doped source/drain regions 164 are positioned on either side of a channel region 163 under gate electrode 162 and second gate dielectric 140. The second gate dielectric 140 is preferably a PNO film having a nitrogen concentration that is less than the nitrogen concentration of the first gate dielectric 120. The nitrogen concentration of second gate dielectric 140 is preferably less than approximately 5.0%.

Referring now to FIG. 6 through FIG. 8, an alternative embodiment of the present invention is shown. The processing depicted in FIG. 6 through FIG. 8 follows the processing depicted in FIG. 1 and is an alternative to the processing depicted in FIG. 2 through FIG. 4. Generally, the embodiment depicted in FIGS. 6 through 8 includes forming a low concentration PNO (the PNO having a relatively low nitrogen concentration) selectively over the PMOS regions and then forming a higher concentration PNO over the entire wafer. The nitrogen in the second PNO will increase the nitrogen concentration in the first PNO such that the first PNO overlying the PMOS regions will have a greater nitrogen concentration than the second PNO overlying the NMOS regions.

Referring to FIG. 6 and FIG. 7, following the formation of semiconductor layer 108 as shown in FIG. 1, a first dielectric film 170 is formed selectively over the PMOS region 106 of substrate 102. First dielectric film 170 is preferably a PNO having a relatively low nitrogen concentration (e.g., a nitrogen concentration of less than approximately 4 or 5%). Selective formation of first gate dielectric 170 overlying PMOS regions is achieved using conventional mask and etch techniques. As an example, first gate dielectric 170 is thermally grown and then exposed to a nitrogen plasma and a subsequent anneal to incorporate nitrogen into the thermal silicon dioxide.

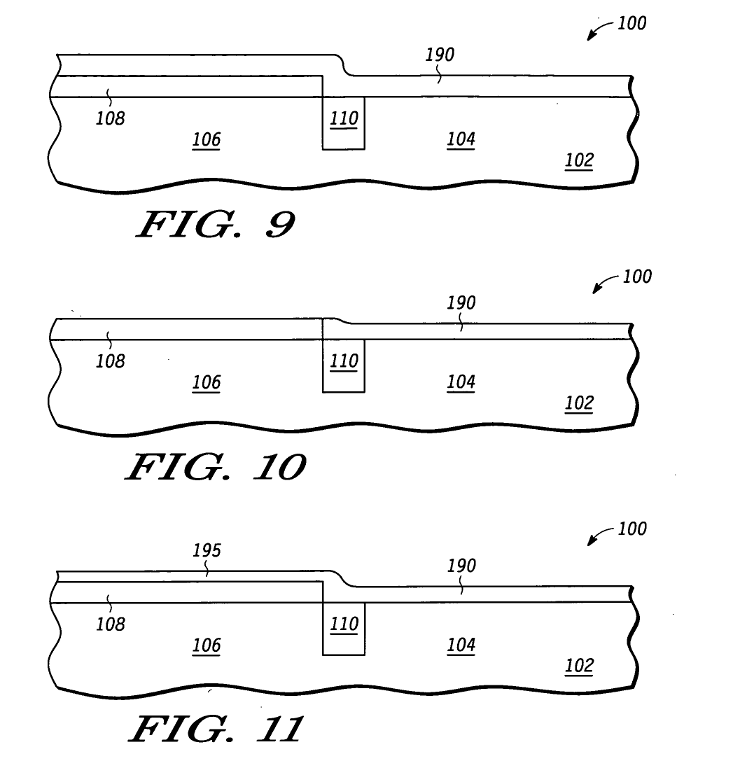

Referring now to FIG. 8, a second gate dielectric 180 is formed non-selectively (no mask) overlying wafer substrate 102. The formation of second gate dielectric 180 preferably produces only a marginal increase in the thickness of first gate dielectric 170. The formation of second gate dielectric 180 does, however, increase the nitrogen concentration of first gate dielectric 170. The nitrogen incorporated into second gate dielectric 180 is also largely incorporated into first gate dielectric 170 thereby resulting in a first gate dielectric having a final nitrogen concentration that is greater than its original nitrogen concentration. The amount by which the nitrogen concentration of first dielectric 170 exceeds the nitrogen concentration of second gate dielectric 180 is approximately equal to the nitrogen concentration used to produce first gate dielectric 170. Following the formation of second gate dielectric 180, processing analogous to the processing depicted in FIG. 5 is carried out to form transistor gate electrodes and source/drain regions.

In a third embodiment, depicted in FIG. 9 through FIG. 11, the PMOS gate dielectric, in addition to having a different nitrogen concentration than the NMOS gate dielectric, also has a different thickness. The processing represented by FIG. 9 through FIG. 11 follows the processing depicted in FIG. 1 and is an alternative to the processing depicted in FIG. 2 through FIG. 4. In FIG. 9, a first gate dielectric 190 is formed non-selectively overlying wafer substrate 102. In one implementation, first dielectric 190 is a PNO that will serve as the NMOS gate dielectric. In this implementation, first gate dielectric 190 has a first thickness, which is relatively thick, and a first nitrogen concentration, which is relatively low. In FIG. 10, first gate dielectric 190 is patterned and etched to remove portions of gate dielectric 190 overlying the PMOS regions 106 of wafer substrate 102.

Following the etch of first gate dielectric 190, a second gate dielectric 195 is formed as depicted in FIG. 11. In the preferred embodiment, second gate dielectric 195 is formed by exposing wafer 100 non-selectively to a second PNO process where the second PNO process preferably has a shorter duration and a higher nitrogen concentration than the PNO process used to form first gate dielectric 190. In this embodiment, first gate dielectric 190 (which will likely serve as the NMOS gate dielectric) is exposed to additional nitrogen during the formation of second gate dielectric 195 (which will likely server as the PMOS gate dielectric). Second gate dielectric 195 is a relatively thin film and has a relatively high concentration of nitrogen. According to one embodiment, for example, the thickness of first gate dielectric 190 is approximately 20 angstroms and the nitrogen concentration is less than approximately 5% while the second gate dielectric 195 has a thickness of approximately 10 angstroms and a nitrogen concentration of at least 5%. The thinness of second gate dielectric 195, coupled with its relatively high nitrogen concentration, produce a film having an EOT that is less than the EOT of first gate dielectric 190 and a nitrogen concentration that is higher than the nitrogen concentration of first gate dielectric 190. Moreover, because second gate dielectric 195 is thinner than first gate dielectric 190, the cycle required to produce second gate dielectric 195 is relatively short. Thus, the amount of nitrogen incorporated into the relatively thicker first gate dielectric 190 during formation of second gate dielectric 195 is limited by the short duration of the second gate dielectric process. Following the formation of second gate dielectric 195, processing analogous to the processing depicted in FIG. 5 is carried out to form transistor gate electrodes and source/drain regions.

In any of the embodiments described above, a combination of two transistor channel materials and two gate dielectric materials is used to optimize the transistor characteristics. In the preferred embodiment, PMOS I_{ON}-I_{OFF} improvement is achieved with PNO having a high nitrogen concentration. The resulting shift in PMOS V_{T} is compensated by the use of compressively stressed SiGe in the PMOS transistor channel.

In the foregoing specification, the invention has been described with reference to specific embodiments. However, one of ordinary skill in the art appreciates that various modifications and changes can be made without departing from the scope of the present invention as set forth in the claims below. For example, the material used for gate electrodes 152 and 162 may differ according to the implementation. The gate electrode may include polysilicon, metals, metal alloys, or a combination thereof. In addition, one type of gate electrode may be used for PMOS transistor 150 while a second type of gate electrode is used for NMOS transistor 160. Similarly, the depicted embodiment shows source/drain regions 154 and 164 for the corresponding transistors 150, but any extension and/or halo implants are not shown. In other implementations, such implants may be found. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A semiconductor fabrication process, comprising:
forming a first plasma nitrided oxide (PNO) gate dielectric overlying a first region of a semiconductor substrate, wherein the first PNO gate dielectric has a first thickness and a first nitrogen concentration;
forming a second PNO gate dielectric overlying a second region of the semiconductor substrate, wherein the second PNO dielectric has a second thickness and a second nitrogen concentration, wherein the second nitrogen concentration differs from the first nitrogen concentration; and
forming a PMOS transistor overlying the first substrate region and an NMOS transistor overlying the second substrate region.

2. The process of claim 1, further comprising, prior to said forming of the first PNO gate dielectric, forming a mobility enhancing channel region overlying the first region of the substrate.

3. The process of claim 2, wherein said forming of the mobility enhancing channel region comprises forming a compressively stressed silicon germanium film overlying the first substrate region.

4. The process of claim 1, wherein said forming of the first PNO gate dielectric comprises selectively forming said first PNO gate dielectric over said first substrate region and wherein said forming of the second PNO gate dielectric comprises selectively forming said second PNO gate dielectric over said second substrate region.

5. The process of claim 4, wherein the nitrogen concentration of the first PNO gate dielectric is greater than the nitrogen concentration of the second dielectric.

6. The process of claim 1, wherein forming the first PNO gate dielectric comprises selectively forming the first PNO gate dielectric over the first substrate region and wherein forming the second PNO gate dielectric comprises non-selectively forming the second gate dielectric, wherein a plasma nitridation step used to form the second PNO gate dielectric contributes to the nitrogen concentration of the first PNO gate dielectric.

6. The process of claim 5, wherein the as-deposited nitrogen concentration of the first gate dielectric is less than the as-deposited nitrogen concentration of the second PNO gate dielectric and further wherein the final nitrogen concentration of the first PNO gate dielectric is greater than the final nitrogen concentration of the second PNO gate dielectric.

7. The process of claim 1, wherein the forming of the first PNO gate dielectric comprises forming the first PNO gate dielectric selectively overlying the second substrate region and wherein forming the second PNO gate dielectric comprises non-selectively forming the second PNO gate dielectric.

8. The process of claim 7, wherein the first nitrogen concentration is lower than the second nitrogen concentration and wherein the first thickness is greater than the second thickness.

9. The process of claim 8, wherein an equivalent oxide thickness (EOT) of the first PNO gate dielectric is greater than an EOT of the second PNO gate dielectric.

10. A semiconductor fabrication process, comprising:
forming a mobility enhancing semiconductor channel region selectively over a first region of a semiconductor substrate;
forming a first gate dielectric overlying the first substrate region and a second gate dielectric overlying a second substrate region, wherein a composition of the first gate dielectric differs from the composition of the second gate dielectric primarily in their respective nitrogen concentrations; and
forming first and second transistors overlying the first and second substrate regions respectively, wherein the mobility enhancing channel region comprises a channel region of the first transistor.

11. The process of claim 10, wherein forming the mobility enhancing semiconductor channel region comprises forming an epitaxial, compressively stressed silicon germanium film selectively overlying the first substrate region.

12. The process of claim 10, wherein forming the first gate dielectric comprises forming a first plasma nitrided oxide (PNO) and wherein forming the second gate dielectric comprises forming a second PNO gate dielectric.

13. The process of claim 12, wherein forming the first PNO gate comprises forming the first PNO gate dielectric selectively overlying the first substrate region and wherein forming the second PNO gate dielectric comprises selectively forming the second PNO gate dielectric overlying the second substrate region.

14. The process of claim 13, wherein the nitrogen concentration of the first PNO gate dielectric exceeds the nitrogen concentration of the second PNO gate dielectric.

15. The process of claim 10, wherein the forming the first gate dielectric comprises forming the first gate dielectric selectively overlying the first substrate region and wherein forming the second gate dielectric comprises forming the second gate dielectric non-selectively.

16. The process of claim 15, wherein the as-formed nitrogen concentration of first gate dielectric is less than the as-formed nitrogen concentration of the second gate dielectric and wherein a final nitrogen concentration of the first gate dielectric is greater than a final nitrogen concentration of the second gate dielectric.

17. The process of claim 10, wherein the first dielectric is formed selectively overlying the second substrate region and wherein the second gate dielectric is formed non-selectively and further wherein a thickness of the first gate dielectric is greater than a thickness of the second gate dielectric and wherein a nitrogen concentration of the first gate dielectric is less than a nitrogen concentration of the second gate dielectric.

18. An integrated circuit, comprising:
a first transistor formed overlying a first region of a semiconductor substrate and a second transistor overlying a second region of the substrate;
wherein the first transistor includes a first silicon-oxygen-nitrogen gate dielectric and the second transistor includes a second silicon-oxygen-nitrogen gate dielectric, wherein the nitrogen concentration of the first and second gate dielectrics differs; and
further wherein the first transistor includes a mobility enhancing channel region.

19. The integrated circuit of claim 18, wherein the first transistor is a PMOS transistor and wherein the first nitrogen concentration exceeds the second nitrogen concentration.

20. The integrated circuit of claim 19, wherein the mobility enhancing channel region comprises compressively stressed silicon germanium channel region.
